(19) United States
(12) Patent Application Publication
(10) Pub. No.: US 2025/0356715 A1
(43) Pub. Date: Nov. 20, 2025

(54) SENSOR ELEMENT, TEST DEVICE, AND METHOD FOR TESTING A DATA CARRIER HAVING A SPIN RESONANCE FEATURE

(71) Applicant: GIESECKE+DEVRIENT CURRENCY TECHNOLOGY GMBH, Munchen (DE)

(72) Inventors: Stephan HUBER, Munchen (DE); Thomas HAPP, Munchen (DE)

(21) Appl. No.: 18/862,723

(22) PCT Filed: May 5, 2023
(86) PCT No.: PCT/EP2023/025210

§ 371 Date: Nov. 4, 2024

(30) Foreign Application Priority Data
May 6, 2022 (DE) 10 2022 001 593.5

(51) Int. Cl. G07D 7/04; G01R 33/34

(52) U.S. Cl. CPC G07D 7/04; G01R 33/34; G07D 2207/00; G07D 2211/00

(57) ABSTRACT

A sensor element is for testing a planar data carrier with a spin resonance feature. The sensor element includes a magnetic core having an air gap into which the planar data carrier can be inserted for testing purposes, a polarization device for generating a static magnetic flux in the air gap, and a resonator device for exciting the spin resonance feature of the data carrier to be tested in the air gap. The resonator device has at least two stripline resonators positioned at different positions in the air gap. The polarization device generates an in-homogeneous magnetic flux in the air gap so that the static magnetic flux has a first field strength at the position of a first stripline resonator and a second, different field strength at the position of a second stripline resonator.

The invention relates to a sensor element for testing the authenticity of a planar data carrier, in particular a banknote, having a spin resonance feature. The invention also relates to a test apparatus having such a sensor element and to a method for testing authenticity by way of such a sensor element or such a test apparatus.

Data carriers such as valuable or identification documents, but also other valuable objects such as branded goods, are often safeguarded by being provided with security elements which allow the authenticity of the data carriers to be verified and which at the same time serve as protection against unauthorized reproduction. The use of security elements having spin resonance features for safeguarding documents and other data carriers within the scope of machine-based authenticity testing is known. To this end, the security elements are provided with substances that have a spin resonance signature. The spin resonance signatures usable for testing authenticity include, in particular, nuclear magnetic resonance (NMR) effects, electron spin resonance (ESR) effects and ferromagnetic resonance (FMR) effects.

To detect the spin resonance signatures when testing banknotes, it is usual for three different magnetic fields to be created in the measurement region of a banknote processing machine, for example. Specifically, this relates to a quasi-static polarization field B₀ which extends parallel to the axial direction (2-direction) of the air gap in a magnetic circuit. A second magnetic field is formed by a modulation field B_{mod} which likewise extends parallel to the z-axis and typically has a frequency f_{mod} in the kHz range. To excite transitions between the split spin energy levels of the spin resonance signature substances, provision is made for an excitation field B₁ which is polarized perpendicular to the B₀-direction. In this context, the excitation field oscillates at the resonant frequency of the material, which is also referred to as Larmor frequency and which is proportional to the polarization field B₀.

To create the polarization field B₀, use is frequently made of a magnetic circuit which guides the magnetic flux from permanent magnets and/or coils to an air gap in which the planar data carriers are tested.

A radiofrequency resonator, for example a stripline resonator, is used to create the excitation field B₁. This is a conductive structure of characteristic length l, which is arranged on a carrier. If the wavelength λ of the incoupled radiofrequency signal matches the dimension 1 of the conductive structure during the authenticity test, then a standing wave can form in the resonator, and the stripline resonator is in resonance with the excitation frequency belonging to the wavelength λ. Since the extent of a stripline resonator is significantly greater in the plane of the carrier than perpendicular thereto, this is also referred to as the plane of the stripline resonator, which corresponds to the plane of the carrier.

When testing a data carrier, for example within the scope of testing authenticity, a spin resonance spectrum of the spin resonance feature is often determined and compared to an expected spectrum on the basis of characteristic features. Typically, spin resonance spectra are recorded in a time-intensive B₀-ramp method (also referred to as B₀-sweep method). In the process, the static polarization field B₀ is slowly varied around the resonance field strength for a fixed frequency of the excitation field B₁, and hence the field strength of the polarization field B₀ is swept. Since the Larmor frequency of a spin resonance feature to be tested is proportional to the polarization field strength B₀, this effectively shifts the excitation frequency vis-à-vis the Larmor frequency, allowing a frequency spectrum of the spin resonance feature to be recorded. Since the change of the field strength of the polarization field B₀ over time within the B₀-ramp method is very much slower than the change of the modulation field B_{mod} and the excitation field B₁ over time, B₀ is preferably referred to as a static magnetic field or static magnetic flux within the scope of this application, even when a ramp field is present.

However, especially in high-speed banknote processing machines, the sensor operation requires short measurement times that do not suffice to allow measurement of the complete spectrum of a spin resonance feature using a ramp (often also: sweep). In that case, frequency spectra can only be recorded using a few measured points, i.e. with a low resolution or over a narrow frequency band. However, a spectrally highly resolved, broadband measurement is desirable for many applications, for example in order to be able to distinguish between feature substances with different Larmor frequencies. Additionally, spin resonance features with a spectral code, for example for different currencies or different denominations, can be used in the case of a high spectral resolution.

Using this as a starting point, the problem addressed by the invention is that of specifying an improved apparatus for testing data carriers having spin resonance features and in particular providing a sensor element which, within a short period of time, allows a spectrally highly resolved and/or broadband measurement of the spin resonance of a data carrier to be tested.

This problem is solved by the features of the independent claims. Developments of the invention are the subject of the dependent claims.

The invention provides a sensor element for testing, in particular testing the authenticity of, a planar data carrier having a spin resonance feature. For example, the planar data carrier can be a banknote. The sensor element contains a magnetic core with an air gap, into which the planar data carrier can be introduced for testing purposes, a polarization device for creating a static magnetic flux in the air gap, and a resonator device for exciting the spin resonance feature of the data carrier to be tested in the air gap.

The resonator device contains at least two stripline resonators arranged at different positions in the air gap. Furthermore, the polarization device creates an inhomogeneous magnetic flux in the air gap in the magnetic core such that the static magnetic flux has a first field strength at the position of a first stripline resonator and has a second, different field strength at the position of a second stripline resonator. The spin resonance feature is preferably an ESR feature.

As explained in more detail below, arranging a plurality of stripline resonators at different positions in an inhomogeneous polarization field allows the simultaneous measurement of the spin resonance at different polarization field strengths and thus allows a higher spectral resolution and/or shorter measurement times. The requirements on a field ramp for measuring a spectral line are also reduced significantly.

In principle, the utilized stripline resonators are particularly distinguished in that their sensitive region is very easily accessible and in that they have a very high fill factor for planar samples, as represented by the banknotes to be tested. Hereinbelow, the stripline resonators are occasionally referred to only as resonators for short too.

In an advantageous configuration, the stripline resonators of the resonator device are arranged in the shape of a one-dimensional array. By preference, the one-dimensional array is arranged in parallel with a gradient of the magnetic flux in the air gap.

In another, likewise preferred configuration, the stripline resonators of the resonator device form a multitrack arrangement having a plurality of parallel tracks, in which each track is formed by a one-dimensional array of stripline resonators. By preference, the one-dimensional array of each track is arranged in parallel with a gradient of the magnetic flux in the air gap.

In particular, the resonator device can contain two, three, four, five or six stripline resonators, wherein a greater number of stripline resonators, for example a multitrack arrangement with two or three tracks with five stripline resonators each, can also be advantageous. Increasing the number of stripline resonators has the advantage of an improved spectral resolution or a shorter required measurement time.

Advantageously, provision is made for the stripline resonators arranged at different positions in the air gap to be each fed by a different signal source.

In an advantageous configuration, the air gap is bounded by two pole faces of the magnetic core, wherein one or both pole faces have a beveled and/or stepped embodiment. In particular, provision can be made for the two pole faces to make an angle with one another, said angle preferably being between 1° and 10°. Since the field strength of the polarization field in the air gap is inversely proportional to the local spacing of the two pole faces, a beveled or stepped embodiment of the pole faces can create a desired inhomogeneous polarization field in the air gap. At the pole faces, the magnetic core preferably consists of a ferromagnetic material with a magnetic permeability μr>>1, i.e. μr greater than 1×10² in particular.

In another, likewise advantageous configuration, the magnetic conductor of the magnetic core is provided with a flux conductor, the magnetic resistance of which differs from the magnetic resistance of the magnetic conductor. Shaping the flux conductor allows the strength of the polarization field in the air gap to be set and a desired inhomogeneous polarization field to be created. In particular, the flux conductor can have a wedge-shaped or step-shaped embodiment in order to create an increasing or decreasing field strength in the air gap, said increase or decrease being linear or step-shaped. If a flux conductor is used to create the inhomogeneous magnetic flux, then the pole faces bounding the air gap are advantageously plane-parallel to one another. This facilitates the undisturbed transport of the data carriers through the air gap. In this case, the pole faces can also be formed by a paramagnetic material with μr≈1, i.e. μr at most 1+10⁻² in particular.

The stripline resonators of the resonator device advantageously have the same resonant frequency; for example, the resonant frequencies of the stripline resonators deviate from one another by less than 1%, preferably by less than 0.1%. By preference, the stripline resonators of the resonator device are even designed and configured for operation in the same spatial mode. In an alternative to that or in addition, provision is furthermore advantageously made for the stripline resonators of the resonator device to have an identical geometric shape, for example a square, a rectangular or a ring shape.

The aforementioned first field strength advantageously differs from the aforementioned second field strength by at least 2%, preferably by at least 5%, in particular by at least 10%.

In particular, the polarization device is capable of creating a linearly increasing or decreasing flux over the extent of the air gap, or a flux that increases or decreases in step-like fashion.

In an advantageous configuration, the sensor element furthermore comprises a modulation device for creating a time-varying magnetic modulation field in the air gap, wherein preferably the modulation frequency is equally high for all stripline resonators of the resonator device. For example, the modulation frequency at the locations of two respective stripline resonators deviates from one another by no more than 2%. The modulation device is advantageously formed by an individual modulation coil arranged in the air gap, in particular by an individual planar coil.

Advantageously, the stripline resonators have a planar embodiment with a principal plane of extent which is perpendicular to the direction of static magnetic flux created by the polarization device. Within the scope of this description, the direction of static magnetic flux is also referred to as the z-direction. The principal plane of extent of the stripline resonators then extends in the xy-plane perpendicular to the z-direction.

The air gap advantageously has a height, i.e. a dimension in the z-direction, of less than 10 mm, preferably of less than 5 mm. This allows the creation of a particularly strong polarization field, i.e. a strong static magnetic flux, in the air gap.

In an advantageous development of the invention, at least some of the aforementioned stripline resonators arranged at different positions with different field strengths of the magnetic flux are respectively replaced by an N×M array of stripline resonators in order to increase the signal-to-noise ratio, where N and M are natural numbers and at least one of the values of N and M is greater than 1, wherein the stripline resonators of the N×M array are all fed by the same signal source in each case and are electrically connected in parallel and/or in series.

In a particularly advantageous configuration, the sensor element furthermore comprises a ramp coil for creating a ramp function of the static magnetic flux.

Advantageously, the resonator device is designed for the excitation of spin resonance signals at a frequency above 1 GHz, in particular between 1 GHz and 10 GHz. Compared to lower frequencies, this allows a higher spectral resolution and a stronger measurement signal.

In particular, the resonator device is also designed to capture spin resonance signals of the spin resonance feature. In particular, the resonator device can record a response signal from the spin resonance feature and output this to a detector. For example, the spin resonances can be determined using a continuous wave (CW) method, a pulsed method or a rapid-scan method.

During data carrier testing, the stripline resonators can be operated both in reflection and in transmission. The advantage of the latter is that the signal branch requires no element such as a circulator which separates the signals propagating to and from the resonator.

Advantageously, the resonator device comprises a planar carrier, on which the stripline resonators are applied. Advantageously, the carrier is formed by a printed circuit board, allowing reproducible and cost-effective production. However, the use of carriers on the basis of ceramic, Teflon or hydrocarbons is also advantageous, especially for reducing dielectric losses in the carrier material.

The invention also contains a test apparatus for testing a planar data carrier, in particular a banknote, having a spin resonance feature, comprising a sensor element of the above-described type and comprising one or more signal source(s) by which the stripline resonators of the resonator device which are arranged at different positions in the air gap are fed.

An advantageous configuration here provides for a plurality of signal sources, by which one of the stripline resonators of the resonator device arranged at different positions in the air gap is fed in each case. However, operating the resonators with the aid of independent signal sources also necessitates the resonators being connected to independent signal branches. This requires much installation space for implementing the circuit, especially in the case of a large number of resonators. By preference, the plurality of signal sources are operated at the same excitation frequency here, for example with a frequency deviation of less than 1%, preferably of less than 0.1%.

It is therefore advantageously likewise possible that the stripline resonators arranged at different positions in the air gap are fed by only a single signal source by way of a multiplexer. In this case, there is only a single signal branch, and all resonators are connected to this signal branch. Thus, this embodiment requires significantly less installation space, and all resonators are readily ensured to be operated at the same excitation frequency. Since this method only allows a measurement by a single resonator at any one time, the switching time t of the multiplexer is preferably matched to the resonators disposed in succession with spacing d such that, in the case of a data carrier moved at the speed v, the spectral individual components are always measured at the same location on the data carrier, i.e. τ=d/v applies. Considered in the transport direction, this method creates gaps between the locations on the data carrier at which the spin resonance is measured; thus, there are also locations at which no measurement is taken.

Alternatively, the switching time of the multiplexer can be reduced to values τ<<d/v. Although this leads to a lower signal-to-noise ratio on account of the shorter measurement time per resonator, the spectral signature of the banknote can in return be captured over greater regions and substantially without gaps.

Advantageously, the test apparatus furthermore comprises a transport device which guides the planar data carriers to be tested along a transport path through the air gap in the magnetic core, wherein the transport path advantageously is parallel to a gradient of the magnetic flux in the air gap. By preference, provision is made here for
either the stripline resonators of the resonator device of the above-described type to be arranged in the form of a one-dimensional array parallel to the transport path,
or the stripline resonators to form a multitrack arrangement of the above-described type, in which each of the tracks is parallel to the transport path.

The transport device is designed and configured in particular for high-speed transport, for example between 1 m/s and 12 m/s, of the planar data carriers to be tested along the transport path.
The invention also contains a method for testing a planar data carrier, in particular a banknote, having a spin resonance feature by means of a sensor element of the described type or a test apparatus of the described type, wherein in the method
a planar data carrier to be tested is guided along a transport path through the air gap in the magnetic core of the aforementioned sensor element, wherein a plurality of stripline resonators of the resonator device are disposed in succession parallel to the transport path,
the polarization device is used to create an inhomogeneous magnetic flux in the air gap in the magnetic core, and preferably a modulation device is used to create a time-varying magnetic modulation field in the air gap, and
the resonator device is used to excite the spin resonance feature of the data carrier to be tested.

In an advantageous procedure, provision is made for
the data carrier to be tested to be guided past the stripline resonators disposed in succession, and for a temporal measurement series of the response signal from the spin resonance feature created post excitation to be recorded by each of the stripline resonators,
measured data belonging to the same measured spot to be in each case identified from the temporal measurement series of the stripline resonators,
spectral information about the spin resonance feature to be derived from the identified measured data, and
the data carrier to be assessed on the basis of the derived spectral information, in particular with regards to authenticity and/or belonging to a data carrier class.

The measured data are advantageously spatially resolved or spatially averaged in this case.

According to an advantageous development of the method, provision is made for
a spatially homogeneous ramp field to be overlaid on the inhomogeneous static magnetic flux such that the entire static magnetic flux in the air gap varies over time between a minimum value and a maximum value,
the spectral information to be derived from the identified measured data taking account of the field strength of the static magnetic flux at the respective measurement time, and
the authenticity of the tested data carrier and/or the belonging of the tested data carrier to one of a plurality of data carrier classes with different spectral signatures to be determined on the basis of the derived spectral information.

As described, the stripline resonators are arranged in succession along a transport direction of the data carrier in a preferred embodiment, and the gradient of the polarization field is parallel to the transport direction. The advantage thereof is that all resonators measure the same track on the data carrier, i.e. the same measured points with a certain time offset. This facilitates data carrier evaluation and testing.

A multitrack setup for creating spatial resolution transversely to the transport direction is also advantageous. To this end, a plurality of tracks, each having a one-dimensional array of resonators, are constructed for the spectral resolution.

In a further advantageous configuration, provision is made for the gradient of the polarization field to point transversely or at an angle to the transport direction of the data carrier. Considered from the transport direction, the stripline resonators of the resonator device can also be arranged next to one another. However, by preference, the resonators are at least partially arranged on a line parallel to the gradient of the polarization field in all configurations since the greatest differences in the field strength B₀ are obtained in this way. However, other arrangements are also possible as a matter of principle; all that needs to be ensured is that at least two resonators of the resonator device are arranged at positions of different polarization field strength.

Further exemplary embodiments and advantages of the invention will be explained below on the basis of the figures, the representation of which dispenses with reproduction that is to scale and in proportion in order to increase clarity.

In the figures:

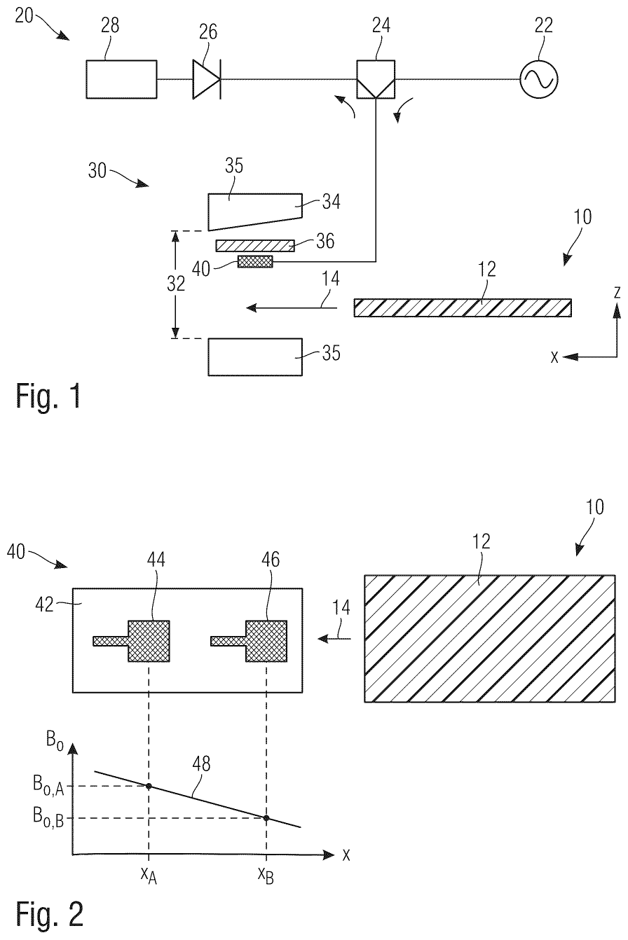

FIG. 1 schematically shows a test apparatus of a banknote processing system for measuring spin resonances of a banknote test object,

FIG. 2 schematically shows a plan view of the resonator device of the test apparatus from FIG. 1 and the supplied banknote test object in the upper part and schematically shows the curve of the inhomogeneous polarization field in the lower part,

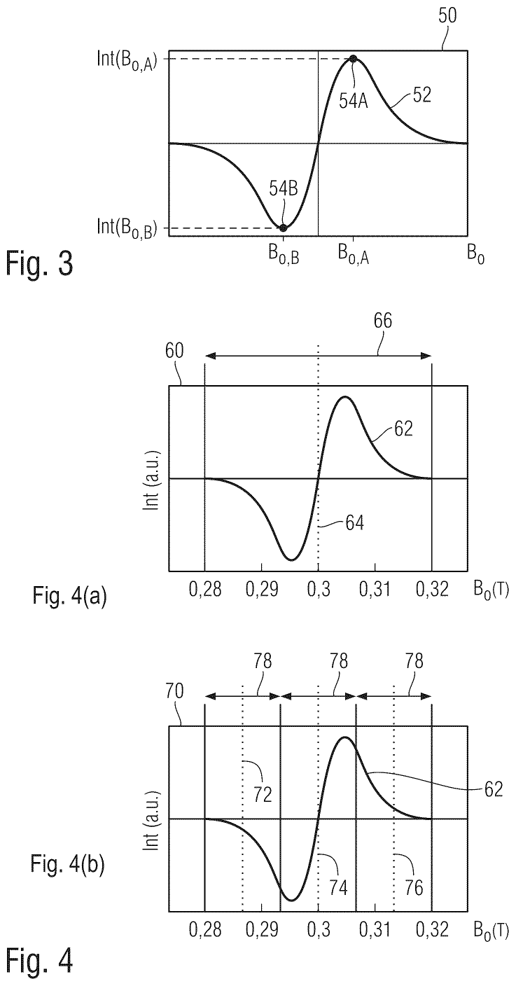

FIG. 3 shows the simplified spectrum of a spin resonance line as a function of polarization field B₀ for a fixed excitation frequency,

FIG. 4 shows diagrams to illustrate the recording of the spin resonance spectrum of the spin resonance line from FIG. 3, using a conventional sensor element in (a) and using a sensor element according to the invention in (b),

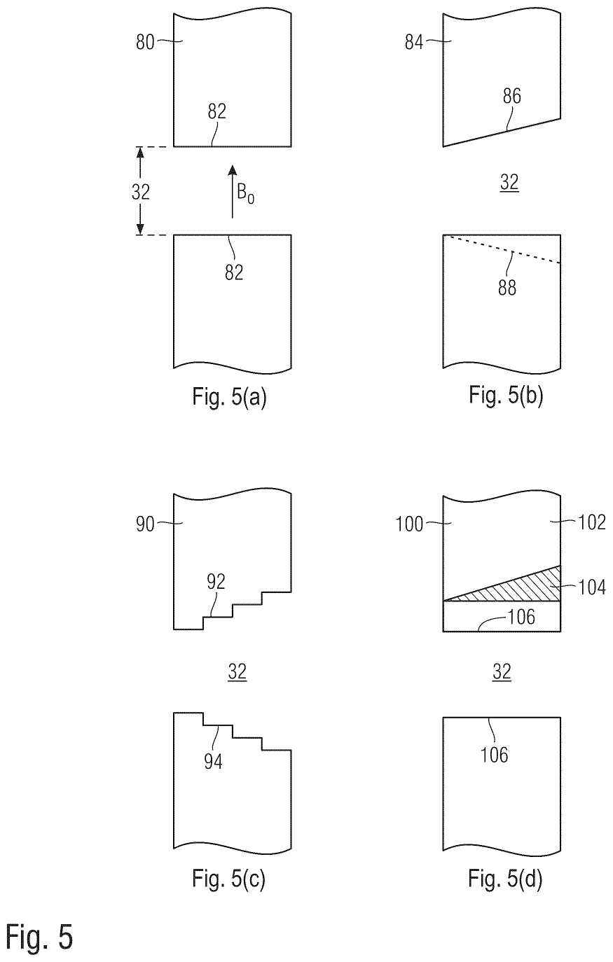

FIG. 5 shows a conventional polarization device in (a) and polarization devices for creating an inhomogeneous magnetic flux in the air gap of a magnetic circuit in (b) to (d),

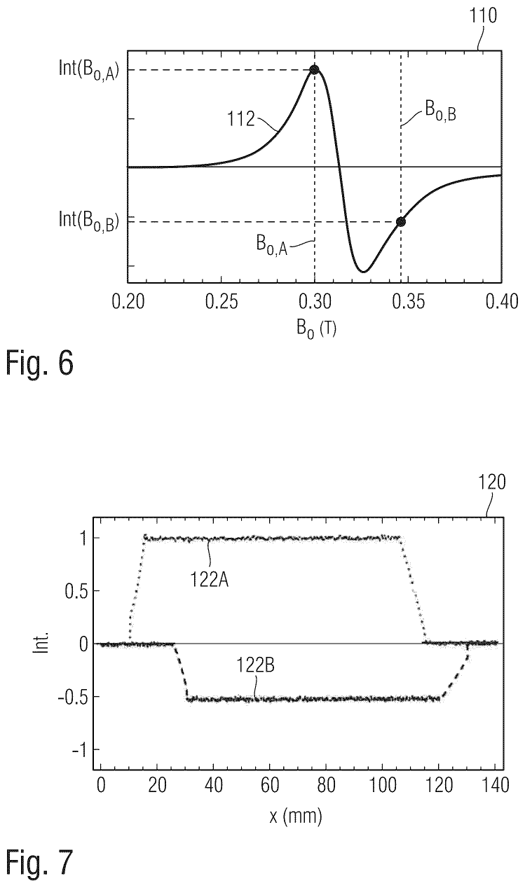

FIG. 6 shows the spectrum of the spin resonance feature of a paper sample, and

FIG. 7 shows signal curves when measuring the spin resonance feature of the paper sample from FIG. 6 using a sensor element according to the invention.

The invention is now explained using the example of testing the authenticity of banknotes. In this respect, FIG. 1 schematically shows a test apparatus 20 of a banknote processing system for measuring spin resonances of a banknote test object 10.

The banknote test object 10 has a spin resonance feature 12, the characteristic properties of which serve to verify the authenticity of the banknote. The spin resonance feature can only be present in a portion of the banknote or can also extend over the entire area of the banknote test object like in the exemplary embodiment shown.

The test apparatus 20 contains a sensor element 30 having a magnetic core 35 with an air gap 32, through which the banknote test object 10 is guided along a transport path 14 during authenticity testing. To detect spin resonance signatures of the spin resonance feature 12, the sensor element 30 creates three different magnetic fields in a measurement region of the air gap 32.

Firstly, a polarization device 34 creates a static magnetic flux parallel to the z-axis in the measurement region. As described in more detail below, the polarization device 34 creates an inhomogeneous magnetic flux in the air gap 32 such that the field strength of the polarization field B₀ has different magnitudes at different points along the transport path 14.

Secondly, a modulation device 36 creates a time-varying magnetic modulation field in the air gap, said magnetic modulation field likewise extending parallel to the z-axis and having a modulation frequency f_{Mod} in the range between 1 kHz and 1 MHz. Finally, a resonator device 40 arranged in the air gap 32 creates an excitation field B₁ which induces energy transitions between the spin energy levels in the spin resonance feature 12. In this case, the resonator device 40 contains at least two stripline resonators arranged at different positions in the air gap and experiencing different field strengths on account of the inhomogeneity of the magnetic flux.

The frequency of the excitation field is typically above 1 GHz and is matched to the Larmor frequency of the spin resonance feature 12 to be detected in order to be able to measure the spin resonance signature of the latter and use this for authenticity testing. To this end, the test apparatus 20 contains a signal source 22, the excitation frequency f_{MW} of which corresponds to the expected Larmor frequency of the spin resonance feature 12. The excitation signal from the signal source 22 is supplied via a duplexer 24 to a resonator device 40 and creates an alternating magnetic field of the frequency f_{MW} there.

In addition to the aforementioned elements, the test apparatus 20 contains a detector diode 26 for measuring the radiofrequency power reflected by the resonator device 40 and an evaluation unit 28 for evaluating and optionally displaying the measurement result. If the spin resonance feature 12 resonates at an incoupled frequency f_{MW}, then there is a change in the resonator quality and hence a change in the power reflected by the stripline resonators. On account of the modulation of the static polarization field brought about by the modulation device 36, the precise value of the Larmor frequency of the sample oscillates, and so the measurement signal obtained is amplitude-modulated with the modulation frequency.

To explain the peculiarities of the present invention in detail, FIG. 2 schematically shows, in plan view in the upper part of the figure, a resonator device 40 according to an exemplary embodiment of the invention with a carrier 42 and the first and second stripline resonators 44, 46 arranged on the carrier. The two stripline resonators 44, 46 are arranged in succession in the transport direction 14 and are therefore successively swept over by the spin resonance feature 12 of the banknote 10 with a time offset. The two stripline resonators 44, 46 are connected independently of one another, but have an identical geometric shape and identical resonant frequencies f.

The lower part of FIG. 2 schematically shows the curve 48 of the inhomogeneous polarization field B₀ along the x-direction and in particular at the location of the stripline resonators 44, 46. In the exemplary embodiment, the field strength of the polarization field B₀ exhibits a linear profile along the transport direction 14. A first stripline resonator 44 is situated at a position x_{A} with the polarization field strength B_{0,A}, while the second stripline resonator 46 initially swept over by the banknote 10 is situated at a position x_{B} with the smaller polarization field strength B_{0,B}.

To further explain the functionality of the present invention, the diagram 50 in FIG. 3 shows the simplified spectrum 52 of a spin resonance line, presently the spin resonance line of the spin resonance feature 12 of the banknote 10 for example, as a function of the polarization field B₀ for a fixed excitation frequency f. In this case, the maximum can be located to the left or right of center, depending on the details of the electronic detection circuit.

Since the Larmor frequency of the spin resonance feature 12 is proportional to the polarization field B₀, the curve profile 52 depicted in FIG. 3 corresponds to a frequency spectrum of the spin resonance line at the same time. In the curve profile 52, two characteristic spectral components 54A, 54B are plotted at the aforementioned polarization field strengths B_{0,A} and B_{0,B} at the location of the resonators 44 and 46, respectively.

If the banknote 10 with the spin resonance feature 12 is swept over the resonator device 40 in FIG. 2 at a specific field strength of the polarization field created by the polarization device 34, then each of the two stripline resonators 44, 46 detects the spectral component 54A or 54B of the spin resonance feature 12 belonging to the resonant frequency thereof.

Specifically, the stripline resonator 44 at the position x_{A} measures the spectral intensity Int(B_{0,A)} of the spectral component 54A belonging to the field strength B_{0,A,} and the stripline resonator 46 at the position x_{B} measures the spectral intensity Int(B_{0,B}) of the spectral component 54B belonging to the field strength B_{0,B}.

As already mentioned in principle above, the static magnetic field B₀ of the polarization device 34 is additionally varied around the resonance field strength with the aid of a ramp coil in the case of a real authenticity test and thus sweep through the field strength of the polarization field B₀ for a fixed frequency f of the excitation field in order to allow a frequency spectrum of the resonance of the feature 12 to be recorded.

The advantage of designs according to the invention is explained in detail with reference to the diagrams 60, 70 in FIG. 4, using the example of a spin resonance feature 12 with only one spin resonance line. The spin resonance line 62 of the feature 12 depicted in simplified fashion in the figures has for example a line width—corresponding to the distance from minimum to maximum—of 10 mT in the space of the polarization field strength.

If a conventional individual resonator is used to record the spin resonance spectrum, then a field ramp 66 over a range of approximately 40 mT is required for a complete capture of the spectral signature in the event of a line width of 10 mT, as illustrated in FIG. 4(a).

In the illustrated comparison example, the spectrum is recorded in a homogeneous polarization field using an individual resonator at a resonant frequency of f=8.41 GHz. This frequency just corresponds to the Larmor frequency of the spin resonance feature 12 at the resonance field strength 64, in this case 300 mT for example. As shown in FIG. 4(a), a field ramp 66 with an amplitude from −20 mT to +20 mT must be swept around the resonance field strength 64 in order to be able to completely measure the spin resonance line 62 with its line width of 10 mT. Such a large field ramp is linked with long measurement times and high power consumption.

By contrast, a substantially shorter measurement time and a substantially lower power consumption can be achieved if an inhomogeneous polarization field and a resonator device 40 having a plurality of spaced-apart stripline resonators according to the present invention are used to record the spectrum.

With reference to FIG. 4(b), the resonator device 40 of a sensor element 30 according to the invention contains e.g. three stripline resonators which are arranged in succession spaced apart in the transport direction and which all have a resonant frequency of f=8.41 GHz. In the exemplary embodiment, the stripline resonators are arranged in the air gap and matched to the inhomogeneous magnetic flux created by the polarization device 34, in such a way that there is a field strength 72 of 287 mT at the position of the first stripline resonator, a field strength 74 of 300 mT at the position of the second stripline resonator and a field strength 76 of 313 mT at the position of the third stripline resonator.

Thus, at the fixed excitation frequency of e.g. f=8.41 GHz, the spin resonance signal from the feature 12 can be measured simultaneously at three different polarization field strengths 72, 74, 76. As evident from FIG. 4(b), a substantially smaller field ramp 78 with an amplitude of only approximately −6.5 mT to 6.5 mT, corresponding substantially to a third of the amplitude of the conventionally required field ramp 66 from FIG. 4(a), then is sufficient to fully capture the spectral signature of the spin resonance line 62.

There are a number of options for creating an inhomogeneous magnetic flux in the air gap of the magnetic circuit, as illustrated with reference to FIG. 5 on the basis of a few advantageous configurations. In the case of a conventional magnetic core 80, the pole faces 82 that form the air gap 32 of the homogeneous magnetic core are arranged in plane-parallel fashion, as shown in FIG. 5(a). In the case of such a homogeneous magnetic core 80, the polarization device creates a homogeneous magnetic field B₀ unsuitable for the present invention in the air gap 32.

In the case of a magnetic core 84 according to a first exemplary embodiment of the invention, one of the pole faces 86 of the magnetic core 84 is beveled at a defined angle, as depicted in FIG. 5(b). Both pole faces 86, 88 of the magnetic core 84 can also be beveled, as is likewise indicated in FIG. 5(b). The angle made by the two pole faces lies between 1° and 10° in particular, for example 5°. A magnetic core 84 with beveled pole faces 86 or 86, 88 is simple to realize from a mechanical point of view. In this case, the field strength B₀ in the air gap 32 varies inversely proportionally to the local distance between the pole faces; for example, the field strength of the polarization field B₀ drops linearly from left to right in the orientation of FIG. 5(b).

In another exemplary embodiment, one or both pole faces of the magnetic core 90 can also have a stepped embodiment as shown in the exemplary embodiment of FIG. 5(c), in which both pole faces 92, 94 have a step-shaped embodiment. In this case, the field strength B₀ in the air gap 32 has a step-shaped profile and for example reduces in step-shaped fashion from left to right in the orientation of FIG. 5(c). A step-shaped profile of the polarization field B₀ is advantageous in that the stripline resonators can each be arranged in a region of locally constant field strength, and so the stripline resonators experience a different polarization field B_{0,A}, B_{0,B} etc. which however is constant over their planar extent in each case.

A magnetic core 100 according to a further exemplary embodiment is shown in FIG. 5(d). In this exemplary embodiment, the magnetic conductor 102 of the magnetic core 100 is provided with a wedge-shaped flux conductor 104, the magnetic resistance of which is greater than the magnetic resistance of the conductor 102 itself. Due to its wedge shape, the flux conductor 104 leads to a spatially dependent variation of the magnetic field created in the air gap 32, and hence to an inhomogeneous polarization field.

A desired profile of the inhomogeneous polarization field can be set by way of the shape of the flux conductor 104. For example, the wedge shape shown in FIG. 5(d) leads to a linear increase or decrease of the polarization field in the air gap. A step-shaped profile of the polarization field B₀ can also be created by way of a step-shaped flux conductor. An advantage of the configuration having a flux conductor 104 consists in the fact that the pole faces 106 of the magnetic core 100 themselves can be plane-parallel, facilitating undisturbed transport of the banknote test objects through the air gap 32. The flux conductor 104 can be located directly at the air gap 32 or, as shown in FIG. 5(d), in the vicinity of the air gap, wherein the pole face 106 however is formed by a further element which for example may consist of the same material as the magnetic core 100.

To demonstrate the functionality of the invention, the behavior of a sensor element having a resonator device with two square λ/2 stripline resonators according to FIG. 2 was simulated.

In this case, the stripline resonators 44, 46 are constructed on a printed circuit board 42 with thickness of 1.5 mm and permittivity of 3.66. The resonators 44, 46 are spaced apart by 15 mm along the banknote transport direction 14. The edge length of the resonators is 7.1 mm, corresponding to a resonant frequency of 9.8 GHz.

The two resonators 44, 46 are operated via circulators with independent 50 Ω signal sources, which run at the same power in continuous wave (CW) mode at the resonant frequency. For coupling to the signal source, the resonators are linked by means of a via in the printed circuit board 42. In this case, the via has a distance of 2.2 mm from the resonator edge. The resonator impedance is 50 Ω at this point.

The resonator device 40 constructed thus is installed in the air gap of a magnetic circuit. The air gap is bounded by two pole faces of a magnetic core 84, wherein, like in FIG. 5(b), one of the two pole faces is plane-parallel with respect to the plane of the banknotes to be tested, while the second pole face 86 is beveled and extends at an angle of 5° with respect to the banknote plane. A polarization field B₀ of inhomogeneous magnetic flux density is created in the air gap as a result of this design.

Specifically, the bevel leads to a polarization field B₀ that increases linearly in the transport direction with a gradient of 3 mT/mm. The field strength of the polarization field B₀ at the position of the second stripline resonator 46 is B_{0,B}=300 mT in the exemplary embodiment, and the field strength at the position of the first stripline resonator 44 is B_{0,A}=345 mT. The inhomogeneous polarization field is overlaid by a spatially constant modulation field B_{mod}.

Subsequently, a paper sample of length 100 mm was loaded homogeneously over its area with a spin resonance feature, the spectrum 112 of which is depicted in the diagram 110 in FIG. 6. The polarization field strengths B_{0,A} and B_{0,B} at the location of the resonators 44, 46 and the associated relative signal intensities Int(B_{0,A}) and Int(B_{0,B}) are likewise plotted.

The paper sample having this spin resonance feature is transported over the resonator device 40, and the two resonators 44, 46 are used to record the signal intensity of the spin resonance feature. The signal curves 122A (resonator 44) and 112B (resonator 46) obtained are depicted in FIG. 7 in the diagram 120, which shows the measured signal intensities as a function of the location x. In this case, the signal curves were normalized to the mean signal intensity of the signal curve 122A.

A ratio of the signal intensity of the first resonator 44 to the signal intensity of the second resonator 46 of 1.0/−0.55 is obtained by averaging the signal intensity in the plateau region of each signal curve 122A, 122B, and this has very good correspondence with the expected ratio Int(B_{0,A})/Int(B_{0,B}) from the resonance spectrum in FIG. 6.

In the arrangements described previously, the stripline resonators of the resonator device are placed and dimensioned such that, in the context of the resonator frequency, the field strength of the polarization field B₀ at the position of the resonators is substantially located within the line width of the Larmor frequency to be measured. However, it is also possible to place a stripline resonator in such a way that the field strength present there does not correspond to any of the expected Larmor frequencies.

Then. negative verification can be performed with such a resonator. i.e. no spin resonance signal is expected for this resonator in the case of a real banknote.

### LIST OF REFERENCE SIGNS

10 Banknote test object
12 Spin resonance feature
14 Transport path
20 Test apparatus
22 Signal source
24 Duplexer
26 Detector diode
28 Evaluation unit
30 Sensor element
32 Air gap
34 Polarization device
35 Magnetic core
36 Modulation device
40 Resonator device
42 Carrier
44, 46 Stripline resonators
48 Curve of the inhomogeneous polarization field
50 Diagram
52 Spectrum of a spin resonance line
54A, 54B Spectral components
60 Diagram
62 Spin resonance line
64 Resonance field strength
66 Field ramp
70 Diagram
72, 74, 76 Polarization field strengths
78 Field ramp
80 Polarization device
82 Plane-parallel pole faces
84 Polarization device
86,88 Beveled pole faces
90 Polarization device
92.94 Step-shaped pole faces
100 Polarization device
102 Magnetic conductor
104 Flux conductor
106 Plane-parallel pole faces
110 Diagram
112 Spectrum of the spin resonance feature
120 Diagram
122A, 122B Signal curves

1.-21. (canceled)

22. A sensor element for testing a planar data carrier having a spin resonance feature, comprising:
a magnetic core having an air gap, into which the planar data carrier can be introduced for testing purposes,
a polarization device for creating a static magnetic flux in the air gap, and
a resonator device for exciting the spin resonance feature of the data carrier to be tested in the air gap,
wherein the resonator device contains at least two stripline resonators arranged at different positions in the air gap, and
the polarization device creates an inhomogeneous magnetic flux in the air gap in the magnetic core such that the static magnetic flux has a first field strength at the position of a first stripline resonator and has a second, different field strength at the position of a second stripline resonator.

23. The sensor element according to claim 21, wherein the stripline resonators of the resonator device are arranged in the shape of a one-dimensional array, in that the one-dimensional array is arranged in parallel with a gradient of the magnetic flux in the air gap.

24. The sensor element according to claim 21, wherein the stripline resonators of the resonator device form a multitrack arrangement having a plurality of parallel tracks, in which each track is formed by a one-dimensional array of stripline resonators,
wherein the one-dimensional array of each track is arranged in parallel with a gradient of the magnetic flux in the air gap.

25. The sensor element according to claim 21, wherein the stripline resonators arranged at different positions in the air gap are each fed by a different signal source.

26. The sensor element according to claim 21 wherein the air gap is bounded by two pole faces of the magnetic core,
wherein one or both pole faces have a beveled and/or stepped embodiment.

27. The sensor element according to claim 26, wherein the two pole faces make an angle with one another.

28. The sensor element according to claim 21, wherein the stripline resonators of the resonator device have the same resonant frequency, in that the stripline resonators moreover are designed and configured to test the spin resonance feature in the same spatial mode of the excitation field, in that the stripline resonators have an identical geometric shape.

29. The sensor element according to claim 21, wherein the aforementioned first field strength differs by at least 2% from the aforementioned second field strength.

30. The sensor element according to claim 21, wherein the sensor element comprises a modulation device for creating a time-varying magnetic modulation field in the air gap,
wherein the modulation frequency is equally high at the location of each of the stripline resonators of the resonator device.

31. The sensor element according to claim 30, wherein the modulation device is formed by an individual modulation coil arranged in the air gap, by an individual planar coil.

32. The sensor element according to claim 21, wherein the stripline resonators have a planar embodiment with a principal plane of extent which is perpendicular to the direction of static magnetic flux created by the polarization device.

33. The sensor element according to claim 21, wherein the air gap has a height of less than 10 mm.

34. The sensor element according to claim 21, wherein the sensor element comprises a ramp coil for creating a ramp function of the static magnetic flux.

35. A test apparatus for testing a planar data carrier having a spin resonance feature, comprising:
a sensor element according to claim 21 and
one or more signal source(s) by which the stripline resonators of the resonator device which are arranged at different positions in the air gap are fed.

36. The test apparatus according to claim 35, wherein provision is made for a plurality of signal sources, by which one of the stripline resonators of the resonator device arranged at different positions in the air gap is fed in each case.

37. The test apparatus according to claim 35, comprising a transport device which guides the planar data carriers to be tested along a transport path through the air gap in the magnetic core,
wherein the transport path advantageously is parallel to a gradient of the magnetic flux in the air gap;
wherein the stripline resonators of the resonator device are arranged in the shape of a one-dimensional array, in that the one-dimensional array is arranged in parallel with a gradient of the magnetic flux in the air gap, wherein either the stripline resonators of the resonator device are arranged in the form of a one-dimensional array parallel to the transport path; or
wherein the stripline resonators of the resonator device form a multitrack arrangement having a plurality of parallel tracks, in which each track is formed by a one-dimensional array of stripline resonators, wherein the one-dimensional array of each track is arranged in parallel with a gradient of the magnetic flux in the air gap, wherein the stripline resonators form a multitrack arrangement in which each of the tracks is parallel to the transport path.

38. The test apparatus according to claim 37, wherein the transport device is designed and configured for high-speed transport of the planar data carriers to be tested along the transport path.

39. A method for testing a planar data carrier having a spin resonance feature by means of a sensor element or a test apparatus according to claim 35, wherein in the method
a planar data carrier to be tested is guided along a transport path through the air gap in the magnetic core of the aforementioned sensor element,
wherein a plurality of stripline resonators of the resonator device are disposed in succession parallel to the transport path,
the polarization device is used to create an inhomogeneous magnetic flux in the air gap in the magnetic core, and a modulation device is used to create a time-varying magnetic modulation field in the air gap, and
the resonator device is used to excite the spin resonance feature of the data carrier to be tested.

40. The method according to claim 39, wherein
the data carrier to be tested is guided past the stripline resonators disposed in succession, and a temporal measurement series of the response signal from the spin resonance feature created post excitation is recorded by each of the stripline resonators,
measured data belonging to the same measured spot are in each case identified from the temporal measurement series of the stripline resonators,
spectral information about the spin resonance feature is derived from the identified measured data, and
the data carrier is assessed on the basis of the derived spectral information, with regards to authenticity and/or belonging to a data carrier class.

41. The method according to claim 39, wherein the measured data are spatially resolved or spatially averaged.

42. The method according to claim 39, wherein a spatially homogeneous ramp field is overlaid on the inhomogeneous static magnetic flux such that the entire static magnetic flux in the air gap varies over time between a minimum value and a maximum value,
the spectral information is derived from the identified measured data taking account of the field strength of the static magnetic flux at the respective measurement time, and
the authenticity of the tested data carrier and/or the belonging of the tested data carrier to one of a plurality of data carrier classes with different spectral signatures is determined on the basis of the derived spectral information.
